(19) United States
(12) Patent Application Publication
(10) Pub. No.: US 2024/0130165 A1
(43) Pub. Date: Apr. 18, 2024

(54) DISPLAY DEVICE

(71) Applicant: Japan Display Inc., Tokyo (JP)

(72) Inventors: Hidekazu MIYAKE, Tokyo (JP); Naoki TOKUDA, Tokyo (JP)

(73) Assignee: Japan Display Inc., Tokyo (JP)

(21) Appl. No.: 18/483,529

(22) Filed: Oct. 10, 2023

(30) Foreign Application Priority Data
Oct. 12, 2022 (JP) 2022-163997

(51) Int. Cl. H10K 59/122; H10K 59/12; H10K 59/80

(52) U.S. Cl. CPC H10K 59/122; H10K 59/1201; H10K 59/873; H10K 59/352

(57) ABSTRACT

According to one embodiment, a display device includes a plurality of display elements and a partition which surrounds each of the plurality of display elements. The display elements each include a lower electrode, an upper electrode opposing the lower electrode and an organic layer disposed between the lower electrode and the upper electrode. The partition includes a conductive lower portion and an upper portion protruding from a side surface of the lower portion. Further, the partition includes an aperture through which the lower portion and the upper portion penetrate.

### CROSS-REFERENCE TO RELATED APPLICATIONS

This application is based upon and claims the benefit of priority from Japanese Patent Application No. 2022-163997 filed Oct. 12, 2022, the entire contents of which are incorporated herein by reference.

### FIELD

Embodiments described herein relate generally to a display device.

### BACKGROUND

In recent years, display devices to which an organic light-emitting diode (OLED) is applied as a display element have been put into practical use. Such a display element comprises a lower electrode, an organic layer which covers the lower electrode, and an upper electrode which covers the organic layer.

Here, in some cases, a light-receiving element such as a sensor or camera that detects ambient light may be placed over the display area where a plurality of display elements are arranged. In such cases, if the light transparency of the display area is low, the detection accuracy of the light-receiving element may decrease.

### BRIEF DESCRIPTION OF THE DRAWINGS

FIG. 1 is a diagram showing a configuration example of a display device according to the first embodiment.

FIG. 2 is a plan view schematically showing an example of layout of subpixels.

FIG. 3 is a schematic cross-sectional view of the display device taken along line III-III in FIG. 2.

FIG. 4 is a schematic cross-sectional view of the display device taken along line IV-IV in FIG. 2.

FIG. 5 is a flowchart showing an example of a method of manufacturing a display device.

FIG. 6 is a schematic cross-sectional view of a part of the manufacturing process of the display device.

FIG. 7 is a schematic cross-sectional view showing a manufacturing process, which follows that of FIG. 6.

FIG. 8 is a schematic cross-sectional view showing a manufacturing process, which follows that of FIG. 7.

FIG. 9 is a schematic cross-sectional view showing a manufacturing process, which follows that of FIG. 8.

FIG. 10 is a schematic cross-sectional view showing a manufacturing process, which follows that of FIG. 9.

FIG. 11 is a schematic cross-sectional view showing a manufacturing process, which follows that of FIG. 10.

FIG. 12 is a schematic cross-sectional view showing a manufacturing process, which follows that of FIG. 11.

FIG. 13 is a schematic cross-sectional view showing a manufacturing process, which follows that of FIG. 12.

FIG. 14 is a schematic cross-sectional view showing a manufacturing process, which follows that of FIG. 13.

FIG. 15 is a schematic cross-sectional view showing a manufacturing process, which follows that of FIG. 14.

FIG. 16 is a schematic cross-sectional view showing a configuration example of a display device according to the second embodiment.

FIG. 17 is a plan view schematically showing apertures according to the third embodiment.

FIG. 18 is a plan view schematically showing an example of apertures according to the fourth embodiment.

FIG. 19 is a plan view schematically showing another example of apertures according to the fourth embodiment.

### DETAILED DESCRIPTION

In general, according to one embodiment, a display device includes a plurality of display elements and a partition which surrounds each of the plurality of display elements. The display elements each include a lower electrode, an upper electrode opposing the lower electrode and an organic layer disposed between the lower electrode and the upper electrode, which emits light in response to a potential difference between the lower electrode and the upper electrode. The partition includes a conductive lower portion and an upper portion protruding from a side surface of the lower portion. Further, the partition includes an aperture through which the lower portion and the upper portion penetrate.

According to such configurations, it is possible to provide a display device comprising a display area with enhanced transparency.

Embodiments will be described with reference to the accompanying drawings.

Note that the disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated in the drawings schematically, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction, a direction parallel to the Y-axis is referred to as a second direction, and a direction parallel to the Z-axis is referred to as a third direction. The third direction Z is normal to a plane containing the first direction X and the second direction Y. Further, viewing structural elements parallel to the third direction Z is referred to as plan view.

The display device of this embodiment is an organic electroluminescent display device comprising an organic light-emitting diode (OLED) as a display element, and could be mounted on televisions, personal computers, in-vehicle devices, tablets, smartphones, mobile phones and the like.

### First Embodiment

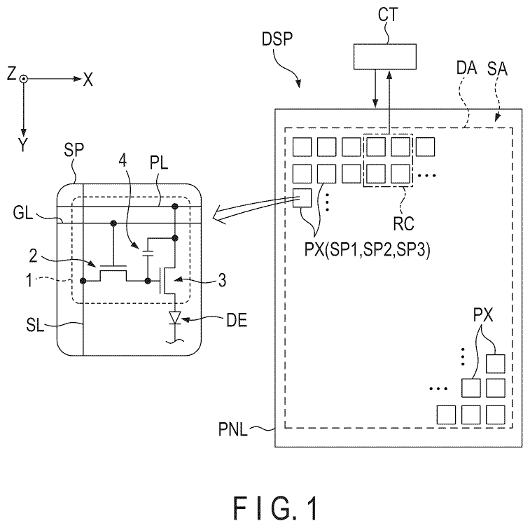

FIG. 1 is a diagram showing a configuration example of a display device DSP according to the first embodiment. The display device DSP comprises a display panel PNL. The display panel PNL includes a display area DA which displays images and a surrounding area SA around the display area DA.

In this embodiment, the shape of the display panel PNL in plan view is rectangular. Note here that the shape of the display panel PNL in plan view is not limited to rectangular, but may as well be some other shape such as a square, circle or oval.

The display area DA comprises a plurality of pixels PX arranged in a matrix along the first direction X and the second direction Y. The pixels PX each include a plurality of subpixels SP. For example, the pixels PX include a blue subpixel SP1, a green subpixel SP2 and a red subpixel SP3. Note that the pixels PX may include a subpixel SP of some other color, such as white, together with or in place of any of the subpixels SP1, SP2 and SP3.

The subpixels SP each comprise a pixel circuit 1 and a display element DE driven by the pixel circuit 1. The display element DE is an organic light emitting diode (OLED) as a light emitting element. The pixel circuit 1 comprises a pixel switch 2, a drive transistor 3 and a capacitor 4. The pixel switch 2 and the drive transistor 3 are switching elements constituted by thin-film transistors, for example.

A gate electrode of the pixel switch 2 is connected to a respective scanning line GL for supplying scanning signals to the pixel circuit 1. One of source and drain electrodes of the pixel switch 2 is connected to a respective signal line SL for supplying video signals to the pixel circuit 1, and the other is connected to a gate electrode of the drive transistor 3 and a capacitor 4. In the drive transistor 3, one of source and drain electrodes is connected to a feed line PL and the capacitor 4, and the other is connected to the display element DE.

Note that the configuration of the pixel circuit 1 is not limited to that of the example shown in the figure. For example, the pixel circuit 1 may as well comprise more thin-film transistors and capacitors.

The display device DSP further comprises a light receiving element RC and a controller CT. The light receiving element RC is, for example, a dimming sensor (ambient light sensor) that detects ambient light and outputs a detection signal according to the detected light. But it is not limited to this example, but the light receiving element RC may as well be another type of element, such as a camera.

The light receiving element RC is disposed on a rear surface side of the display panel PNL, for example, and overlaps the display area DA. The light receiving element RC has a size larger than one pixel PX, for example. In this case, the light receiving element RC overlaps multiple pixels PX.

The controller CT executes various operations for displaying images on the display area DA, such as supplying signals to the pixel circuits and the like. When the light receiving element RC is a light dimming sensor, the controller CT adjusts the brightness of the image displayed on the display area DA based on a detection signal from the light receiving element RC. More specifically, the controller CT increases the brightness of the image as the outdoor light (ambient light) is stronger, and decreases the brightness of the image as the ambient light is weaker. The controller CT may be mounted on the display panel PNL or on a flexible circuit board connected to the display panel PNL or on a rigid substrate connected to the flexible circuit board.

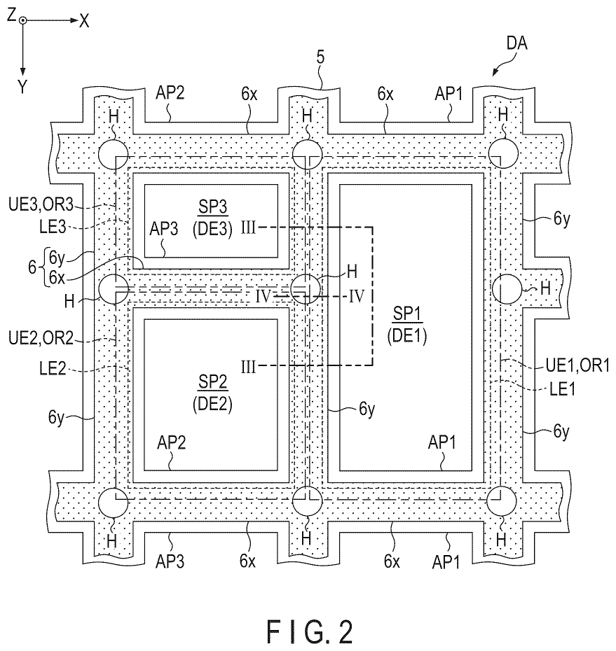

FIG. 2 is a schematic plan view showing an example of layout of the subpixels SP1, SP2 and SP3. In the example shown in FIG. 2, the subpixels SP1 and SP2 are aligned along the first direction X. The subpixels SP1 and SP3 as well are aligned along the first direction X. Further, the subpixels SP2 and SP3 are aligned along the second direction Y.

When the subpixels SP1, SP2 and SP3 have such a layout, rows in each of which a plurality of subpixels SP1 are repeatedly arranged along the second direction Y and rows in each of which subpixels SP2 and SP3 are arranged alternately along the second direction Y in the display area DA. These rows are alternately arranged along the first direction X.

Note that the layout of the subpixels SP1, SP2 and SP3 is not limited to that of the example shown in FIG. 2. As another example, the subpixels SP1, SP2 and SP3 may as well be aligned along the first direction X.

In the display area DA, an insulating rib 5 and a conductive partition 6 are arranged. The rib 5 includes pixel apertures AP1, AP2 and AP3 in the subpixels SP1, SP2 and SP3, respectively. In the example shown in FIG. 2, the pixel aperture AP2 is larger than the pixel aperture AP3 and the pixel aperture AP1 is larger than the pixel aperture AP2.

The subpixel SP1 comprises a lower electrode LE1, an upper electrode UE1 and an organic layer OR1 each overlapping the pixel aperture AP1. The subpixel SP2 comprises a lower electrode LE2, an upper electrode UE2 and an organic layer OR2 each overlapping the pixel aperture AP2, respectively. The subpixel SP3 comprises a lower electrode LE3, an upper electrode UE3 and an organic layer OR3 each overlapping the pixel aperture AP3.

The portions of the lower electrode LE1, the upper electrode UE1 and the organic layer OR1, which overlap the pixel aperture AP1 constitutes the display element DE1 of the subpixel SP1. The portions of the lower electrode LE2, the upper electrode UE2 and the organic layer OR2, which overlap the pixel aperture AP2 constitute the display element DE2 of the subpixel SP2. The portions of the lower electrode LE3, the upper electrode UE3 and the organic layer OR3, which overlap the pixel aperture AP3 constitute the display element DE3 of the subpixel SP3. The display elements DE1, DE2 and DE3 may further include a cap layer, which will be described later. The rib 5 surrounds the display elements DE1, DE2 and DE3.

The partition 6 is placed at the boundary of each pair of subpixels SP adjacent to each other, so as to overlap the rib 5 in plan view. The partition 6 includes a plurality of first partitions 6x extending along the first direction X and a plurality of second partitions 6y extending along the second direction Y.

The first partitions 6x are each disposed between each pair of pixel apertures AP1 adjacent to each other along the second direction Y and between each pair of pixel apertures AP2 and AP3 adjacent to each other along the second direction Y. The second partitions 6y are each disposed between each pair of pixel apertures AP1 and AP2 adjacent to each other along the first direction X and between each pair of pixel apertures AP1 and AP3 adjacent to each other along the first direction X.

In the example shown in FIG. 2, the first partitions 6x and the second partitions 6y are connected to each other. With this structure, the partition 6, as a whole, has a lattice-like shape which surrounds the display elements DE1, DE2 and DE3 and the pixel apertures AP1, AP2 and AP3. It can as well be said that the partition 6 includes apertures in the subpixels SP1, SP2 and SP3, respectively, as in the case of the rib 5.

The partition 6 comprises a plurality of apertures H. The apertures H are sufficiently smaller than the pixel apertures AP1, AP2 and AP3. In this embodiment, the shape of each of the apertures H in plan view is a regular circle. Note that the shape of the apertures H is not limited to that of this example, but may as well be oval or polygonal. Further, not all of the apertures H need to have the same shape as shown in the figure, but a plurality of apertures H of different shapes may as well be provided.

In the example shown in FIG. 2, each aperture H is independent from the pixel apertures AP1, AP2 and AP3. As another example, at least one of the plurality of apertures H may be connected to the pixel apertures AP1, AP2 and AP3.

In the example shown in FIG. 2, the aperture H is provided at each of the intersections of the first partitions 6x and the second partitions 6y. The aperture H may be provided at all of the intersections present in the display area DA, or at some of these intersections.

When the apertures H are not uniformly arranged in the display area DA, the user may feel unevenness while viewing the display area DA. Therefore, it is preferable that the apertures H should be arranged in a uniform density over the entire display area DA. As another example, the apertures H may be provided in the regions which overlap the light receiving elements RC and not in the surrounding regions thereof.

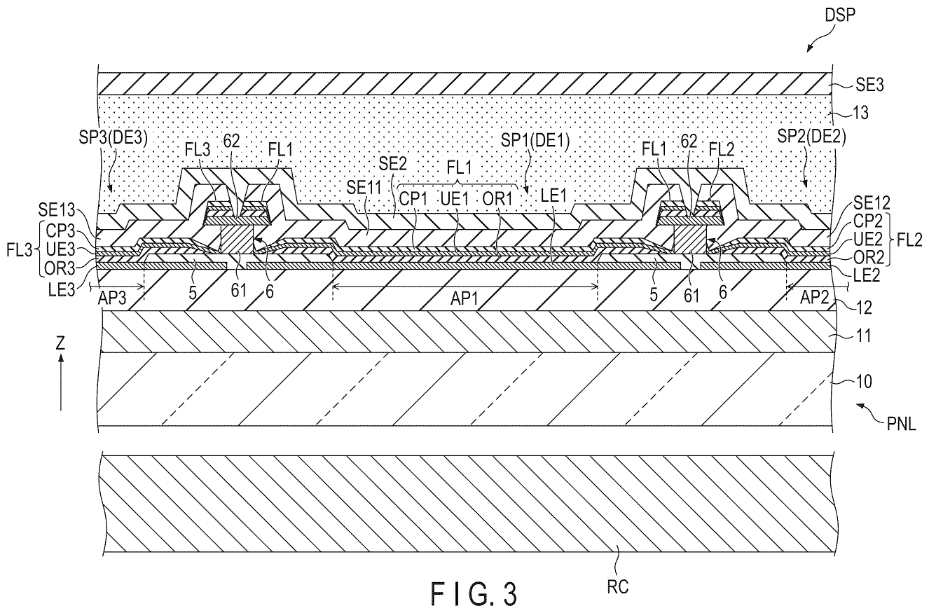

FIG. 3 shows a schematic cross-sectional view of the display device DSP taken along line III-III in FIG. 2. The display panel PNL comprises a substrate 10, a circuit layer 11 disposed on the substrate 10 and an organic insulating layer 12 which covers the circuit layer 11.

The circuit layer 11 includes various circuits and wiring lines, such as the pixel circuit 1, scanning lines GL, signal lines SL, and feed lines PL shown in FIG. 1. The organic insulating layer 12 functions as a planarization film that planarizes unevenness created by the circuit layer 11.

The lower electrodes LE1, LE2 and LE3 are disposed on the organic insulating layer 12. Although not illustrated in the cross section shown in FIG. 3, the lower electrodes LE1, LE2 and LE3 are connected to the pixel circuits 1 of the subpixels SP1, SP2 and SP3, respectively, via contact holes provided in the organic insulating layer 12.

The rib 5 is disposed on the organic insulating layer 12 and the lower electrodes LE1, LE2 and LE3. End portions of the lower electrodes LE1, LE2 and LE3 are covered by the rib 5.

The partition 6 includes a lower portion 61 having conductivity and disposed on the rib 5 and an upper portion 62 disposed on the lower portion 61. The upper portion 62 has a width greater than that of the lower portion 61. With this configuration, in FIG. 3, both end portions of the upper portion 62 protrude beyond respective side surfaces of the lower portion 61. Such a shape of the partition 6 is referred to as overhanging type.

The organic layer OR1 covers the lower electrode LE1 through the pixel aperture AP1. The upper electrode UE1 covers the organic layer OR1 and opposes the lower electrode LE1. The organic layer OR2 covers the lower electrode LE2 through the pixel aperture AP2. The upper electrode UE2 covers the organic layer OR2 and opposes the lower electrode LE2. The organic layer OR3 covers the lower electrode LE3 through the pixel aperture AP3. The upper electrode UE3 covers the organic layer OR3 and opposes the lower electrode LE3.

In the example shown in FIG. 3, the cap layer CP1 is disposed on the upper electrode UE1, the cap layer CP2 is disposed on the upper electrode UE2, and the cap layer CP3 is disposed on the upper electrode UE3. The cap layers CP1, CP2 and CP3 serve as optical adjustment layers that improve the efficiency of extracting light emitted by the organic layers OR1, OR2 and OR3, respectively.

In the following description, a stacked body including the organic layer OR1, the upper electrode UE1 and the cap layer CP1 is referred to as a thin film FL1, a stacked body including the organic layer OR2, the upper electrode UE2 and the cap layer CP2 is referred to as a thin film FL2, and a stacked body including the organic layer OR3, the upper electrode UE3 and the cap layer CP3 is referred to as a thin film FL3.

A portion of the thin film FL1 is located on the upper portion 62. This portion is separated from a portion of the thin film FL1, which is located below the partition 6 (the portion which constitutes the display element DE1). Similarly, a portion of the thin film FL2 is located on the upper portion 62 and this portion is separated from a portion of the thin film FL2, which is located below the partition 6 (the portion which constitutes the display element DE2). Further, a portion of the thin film FL3 is located on the upper portion 62 and the portion is separated from a portion of the thin film FL3, which is located below the partition 6 (the portion which constitutes the display element DE3).

In the subpixels SP1, SP2, and SP3, first sealing layers SE11, SE12 and SE13 are respectively disposed to cover the display elements DE1, DE2 and DE3 individually. The first sealing layer SE11 continuously covers the thin film FL1 and the partition 6 around the subpixel SP1. The first sealing layer SE12 continuously covers the thin film FL2 and the partition 6 around the subpixel SP2. The first sealing layer SE13 continuously covers the thin film FL3 and the partition 6 around the subpixel SP3.

In the example shown in FIG. 3, the thin films FL1 and FL2 on the partition 6 between the subpixels SP1 and SP2 are separated from each other. The thin films FL1 and FL3 on the partition 6 between the subpixels SP1 and SP3 are also separated from each other.

In the example shown in FIG. 3, the end portions of the first sealing layers SE11 and SE12 located on the partition 6 between the subpixels SP1 and SP2 are separated from each other. The end portions of the first sealing layers SE11 and SE13 located on the partition 6 between the subpixels SP1 and SP3 are also separated from each other.

The first sealing layers SE11, SE12 and SE13 are continuously covered by the second sealing layer SE2. With the second sealing layer SE2, the display elements DE1, DE2 and DE3 more securely sealed, thus improving resistance to moisture.

The second sealing layer SE2 is covered by the resin layer 13. The resin layer 13 is covered by the third sealing layer SE3. The second sealing layer SE2, the resin layer 13 and the third sealing layer SE3 are provided over at least the entire display area DA, and parts thereof extend to the surrounding area SA.

A resin layer and/or a sealing layer may further be placed on the third sealing layer SE3. Another optical element, a protective film and a substrate such as cover glass or a touch panel may be placed above the third sealing layer SE3, and this substrate may be adhered to the third sealing layer SE3 via a transparent adhesive layer such as an optical clear adhesive (OCA).

The light receiving element RC is disposed below the substrate 10. The light receiving element RC is supported, for example, by a frame or housing that holds the display panel PNL. A translucent insulating layer or conductive layer may as well be disposed between the light-receiving element RC and the substrate 10.

The substrate 10 is formed of glass, for example. The substrate 10 may as well be formed of a transparent resin material having flexibility. The organic insulating layer 12 is formed of an organic insulating material.

The rib 5, the first sealing layers SE11, SE12 and SE13, the second sealing layer SE2 and the third sealing layer SE3 are each formed of, for example, an inorganic insulating material such as silicon nitride (SiNx), silicon oxide (SiOx) or silicon oxynitride (SiON). The rib 5, the first sealing layers SE11, SE12 and SE13, the second sealing layer SE2 and the third sealing layer SE3 may be formed of different types of inorganic insulating materials, respectively. The rib 5 may as well be formed of an organic insulating material such as polyimide. The resin layer 13 is formed of, for example, a resin material such as acrylic resin.

The lower electrodes LE1, LE2 and LE3 each include an intermediate layer formed of silver (Ag), for example, and a pair of conductive oxide layers which respectively cover an upper surface and lower surface of the intermediate layer, respectively. Each conductive oxide layer can be formed, for example, of a transparent conductive oxide such as indium tin oxide (ITO), indium zinc oxide (IZO) or indium gallium zinc oxide (IGZO).

The upper electrodes UE1, UE2 and UE3 are each formed, for example, of a metallic material such as an alloy of magnesium and silver (MgAg). For example, the lower electrodes LE1, LE2 and LE3 correspond to anodes, and the upper electrodes UE1, UE2 and UE3 correspond to cathodes.

The organic layers OR1, OR2 and OR3 have a stacked layer structure of, for example, a hole injection layer, a hole transport layer, an electron blocking layer, a light emitting layer, a hole blocking layer, an electron transport layer and an electron injection layer. The organic layers OR1, OR2 and OR3 may as well have a so-called tandem structure including multiple light emitting layers.

The cap layers CP1, CP2 and CP3 are formed, for example, of a stacked layer body of a plurality of transparent thin films. The stacked layer body may as well include, as the plurality of thin films, a thin film formed of an inorganic material and a thin film formed by an organic material. Further, these plurality of thin films have refractive indices different from each other. The material of the thin films which constitute the stacked layer body is different from the material of the upper electrodes UE1, UE2 and UE3 and also from the material of the first sealing layers SE11, SE12 and SE13. The cap layers CP1, CP2 and CP3 may be omitted.

The lower portion 61 of the partition 6 is formed, for example, of aluminum (Al). The lower portion 61 may as well be formed of an aluminum alloy such as aluminum-neodymium (AlNd) or may have a stacked layer structure of an aluminum layer and an aluminum alloy layer. Further, the lower portion 61 may include a thin film formed of a metal material different from aluminum or aluminum alloy under the aluminum layer or aluminum alloy layer. Such a thin film can be formed, for example, of molybdenum (Mo).

The upper portion 62 of the partition 6 has a stacked layer structure of a thin film formed, for example, of a metal material such as titanium (Ti) and a thin film formed, for example, of a conductive oxide such as ITO. The upper portion 62 may have a single layer structure of a metal material such as titanium. Further, the upper portion 62 may as well have a single layer or s stacked layer structure of an inorganic insulating material different from that of the first sealing layers SE11, SE12 and SE13.

To the partition 6, a common voltage is supplied. The common voltage is supplied to each of the upper electrodes UE1, UE2 and UE3, which are in contact with a side surface of the lower portion 61. To the lower electrodes LE1, LE2 and LE3, a pixel voltage is supplied through the respective pixel circuits 1 of the subpixels SP1, SP2 and SP3.

When a potential difference is created between the lower electrode LE1 and the upper electrode UE1, the light emitting layer of the organic layer OR1 emits light of a wavelength range of blue color. When a potential difference is created between the lower electrode LE2 and the upper electrode UE2, the light emitting layer of the organic layer OR2 emits light of a wavelength range of green color. When a potential difference is created between the lower electrode LE3 and the upper electrode UE3, the light emitting layer of the organic layer OR3 emits light of a wavelength range of red color.

As another example, the light emitting layers of organic layers OR1, OR2 and OR3 may emit light of the same color (for example, white). In this case, the display device DSP may comprise color filters which convert the light emitted by the light-emitting layers into light of colors corresponding to the subpixels SP1, SP2 and SP3, respectively. Further, the display device DSP may as well comprise layers containing quantum dots that are excited by the light emitted by the light-emitting layers to generate light of colors corresponding to the subpixels SP1, SP2 and SP3, respectively.

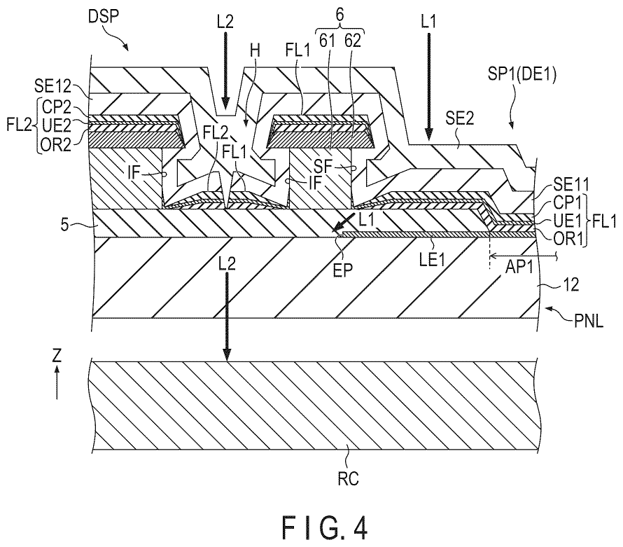

FIG. 4 is a schematic cross-sectional view of the display device DSP taken along line IV-IV in FIG. 2. In this drawing, the substrate 10, the circuit layer 11, the resin layer 13 and the third sealing layer SE3 are omitted.

The lower portion 61 of the partition 6 includes a side surface SF. The upper portion 62 protrudes from the side surface SF. The upper electrode UE1 is in contact with the side surface SF. The portion of the side surface SF, which is not covered by the upper electrode UE1 is covered by the sealing layer SE11.

The aperture H penetrates the lower portion 61 and the upper portion 62. That is, the aperture H includes holes made in the lower portion 61 and the upper portion 62, respectively. The lower portion 61 includes an inner surface IF in the aperture H. The upper portion 62 protrudes to an inner side of the aperture H further than the inner surface IF.

In the example shown in FIG. 4, a thin film FL1 is disposed on the upper portion 62 at the right side of the aperture H and a thin film FL2 is disposed on the upper portion 62 at the left side of the aperture H. The thin films FL1 and FL2 are also disposed on an inner side of the aperture H. The thin films FL1 and FL2 disposed on the inner side of the aperture H are separated from the thin films FL1 and FL2 disposed on the upper portion 62.

The thin film FL1 disposed on the inner side of the aperture H is covered by the sealing layer SE11. Similarly, the thin film FL2 disposed on the inner side of the aperture H is covered by the first sealing layer SE12. The first sealing layers SE11 and SE12 cover the inner surface IF as well.

At least a part of the inner side of the aperture H is filled by the second sealing layer SE2. The second sealing layer SE2 continuously covers the first sealing layers SE11 and SE12 provided on the inner side of the aperture H.

The end portion EP of the lower electrode LE1 is located, for example, below the lower portion 61 and is covered by the rib 5. It is preferable that the aperture H should be provided at a position where it does not overlap the lower electrode LE1 in plan view. In the example of FIG. 4, the end portion EP is located between the aperture H and the pixel aperture AP1. In this case, the entire aperture H does not overlap the lower electrode LE1. As another example, the aperture H may partially overlap the lower electrode LE1.

The light receiving element RC overlaps at least one aperture H in plan view. The light receiving element RC detects external light transmitted through the display panel PNL. The lower electrode LE1 and the partition 6 have are light-shielding properties. Therefore, most of light L1 incident on the display element DE1 is shielded by the display panel PNL. The light L1 can enter the light-receiving element RC through the space between the end portion EP of the lower electrode LE1 and the partition 6. However, the light will be extremely weak.

On the other hand, light L2 traveling toward the aperture H passes through the display panel PNL without being shielded by the partition 6 and the lower electrode LE1. The light receiving element RC detects the light L2 and outputs a detection signal according to its intensity and chromaticity.

When the wiring lines (scanning lines GL, signal lines SL and feed lines PL, etc.) contained in the circuit layer 11 shown in FIG. 2 are located below the partition 6, it is preferable that the aperture H should be larger in width than that of the wiring lines. With this configuration, even when the aperture H and the wiring overlap each other, the intensity of light transmitted through the display panel PNL can be increased.

In FIG. 4, the configuration of the partition 6 surrounding the subpixel SP1 and its vicinity is mainly shown, but the configuration of the partition 6 surrounding the subpixels SP2 and SP3 and its vicinity is also similar to that of the example in FIG. 4. In other words, the plurality of apertures H includes apertures H in which the thin film FL3 and the first sealing layer SE13 are arranged on their inner side. Further, preferably, each aperture H should not overlap any of the lower electrodes LE1, LE2 and LE3.

Now, a method of manufacturing the display device DSP will be described.

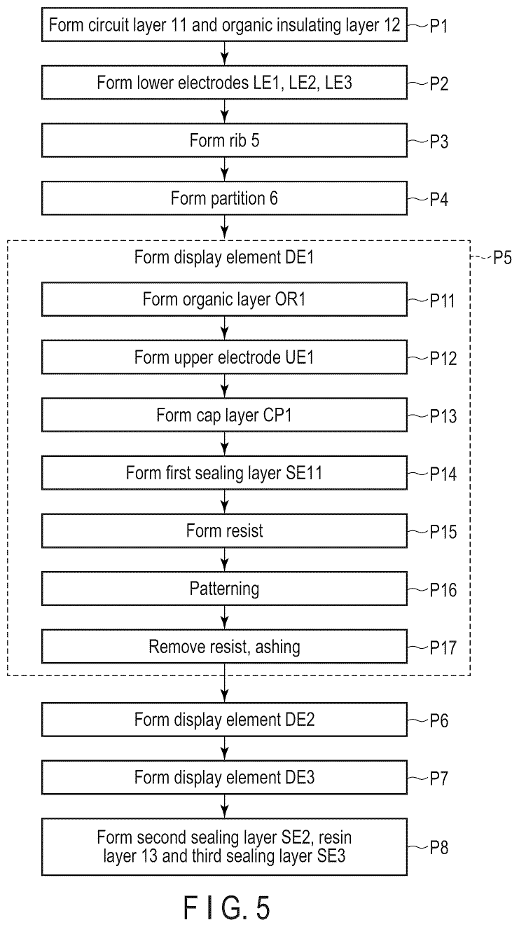

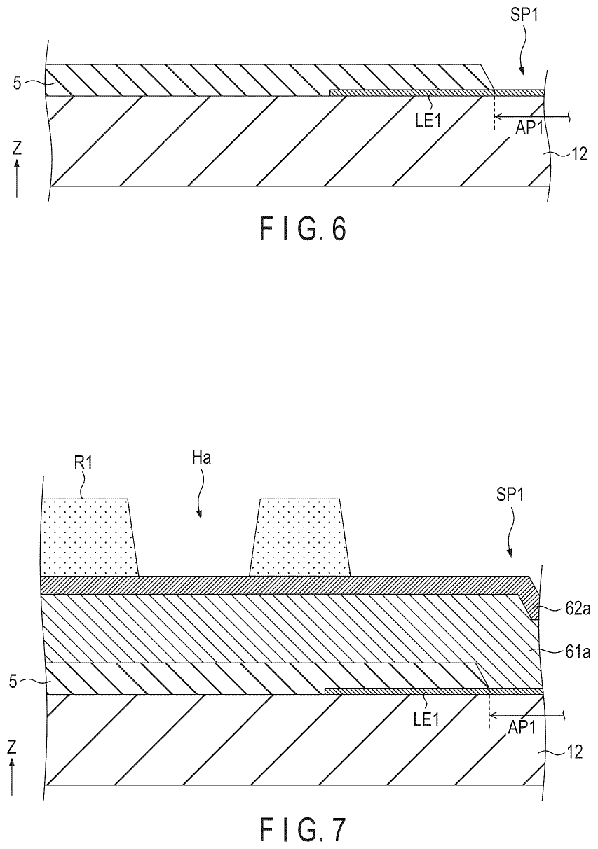

FIG. 5 is a flowchart showing an example of a method of manufacturing the display device DSP. FIGS. 6 to 15 are schematic cross-sectional views each showing a respective part of the process of manufacturing the display device DSP. In FIGS. 6 to 15, the substrate 10 and the circuit layer 11 are omitted from illustration.

In the manufacture of the display device DSP, first, the circuit layer 11 and the organic insulating layer 12 are formed on the substrate 10 (process P1). Further, the lower electrodes LE1, LE2 and LE3 are formed on the organic insulating layer 12 (process P2).

After the process P2, the rib 5 is formed on the lower electrodes LE1, LE2 and LE3 and the organic insulating layer 12 (process P3) as shown in FIG. 6. Further, the partition 6 is formed on the rib 5 (process P4). Note here that the pixel apertures AP1, AP2 and AP3 of the rib 5 may be formed before or after the partition 6.

In the process P4, first, as shown in FIG. 7, a metal layer 61a, which gives rise to the lower portion 61, is formed on the rib 5 and the lower electrodes LE1, LE2 and LE3, and a thin film 62a, which gives rise to the upper portion 62, is formed on the metal layer 61a. Further, a resist R1 is formed over the thin film 62a according to the shape of the partition 6. The resist R1 comprises apertures Ha provided at respective locations where the apertures H are to be formed.

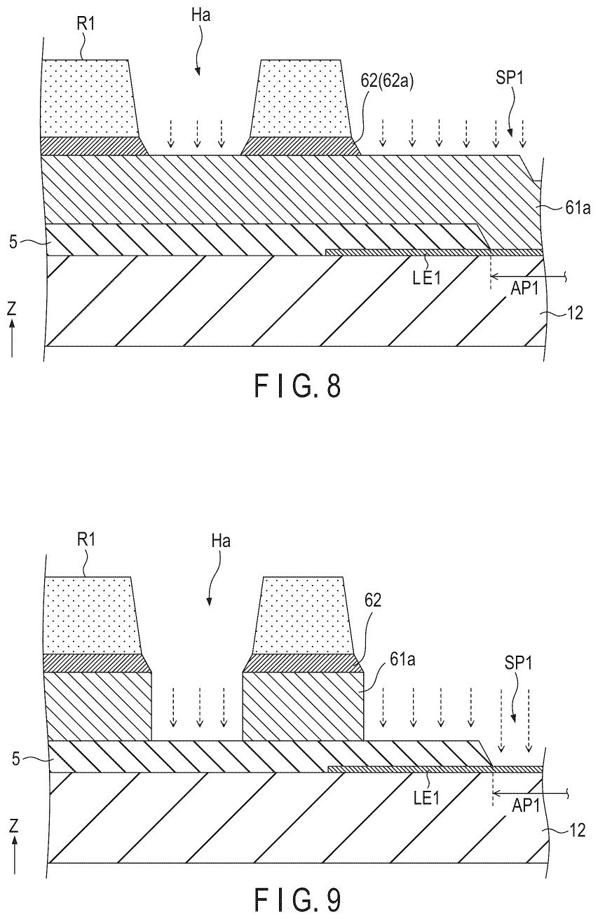

After forming the resist R1, as shown in FIG. 8, the portion of the thin film 62a, which is exposed from the resist R1, is removed, for example, by wet etching. Thus, the upper portion 62 is formed.

Then, anisotropic dry etching is performed to remove the portion of the metal layer 61a, which is exposed from the resist R1 as shown in FIG. 9. Note that in the dry etching, the portion of the metal layer 61a, which is exposed from the resist R1 may be left thin.

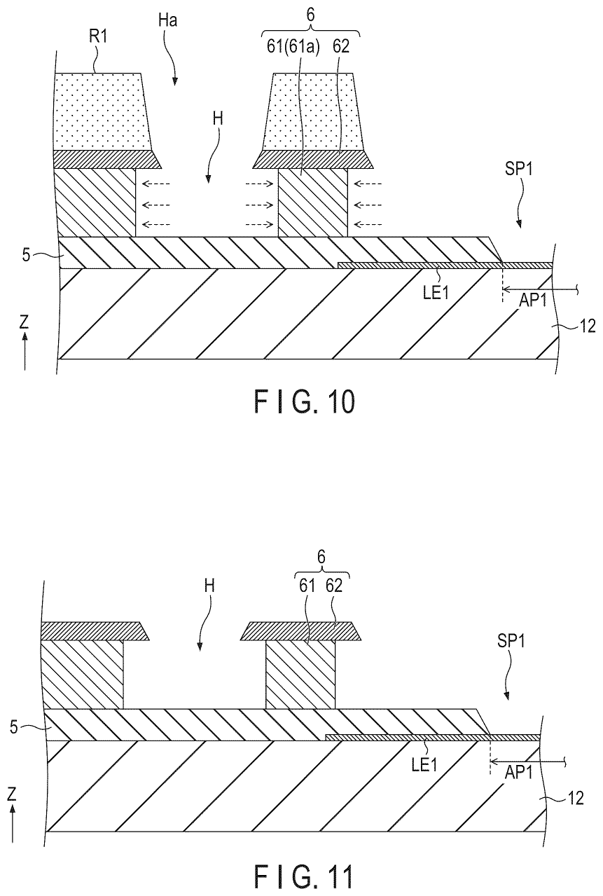

Subsequently, isotropic wet etching is performed to erode side surfaces of the metal layer 61a as shown in FIG. 10. In this manner, the lower portion 61 with more recessed side surfaces than those of the upper portion 62 is formed, thus completing the partition 6. Below the aperture Ha of the resist R1, the aperture H of the partition 6 is formed by a series of etching processes shown in FIGS. 8 to 10. After the completion of the partition 6, the resist R1 is removed by a stripping solution as shown in FIG. 11.

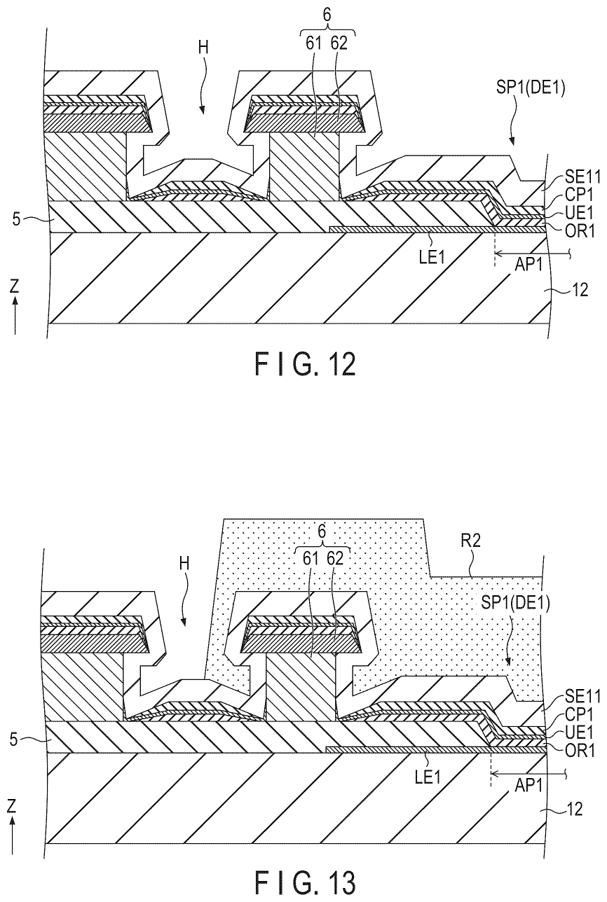

After the process P4, the display element DE1 is formed (process P5). More specifically, as shown in FIG. 12, an organic layer OR1 is formed on the lower electrodes LE1, LE2 and LE3, the rib 5 and the partition 6 by vapor deposition (process P11), an upper electrode UE1 is formed on the organic layer OR1 by vapor deposition (process P12), and a cap layer CP1 is formed on the upper electrode UE1 by vapor deposition (process P13). Further, the first sealing layer SE11 is formed by chemical vapor deposition (CVD) (process P14).

Note that the process P11 includes steps of sequentially forming thin films which constitute the organic layer OR1, such as the hole injection layer, hole transport layer, electron blocking layer, light emitting layer, hole blocking layer, electron transport layer, electron injection layer and the like. Further, the process P13 includes steps of sequentially forming a plurality of thin films which constitute the cap layer CP1.

The organic layer OR1, the upper electrode UE1, the cap layer CP1 and the first sealing layer SE11 are formed at least over the entire display area DA, and are disposed not only in the subpixel SP1 but also in the subpixels SP2 and SP3. The organic layer OR1, the upper electrode UE1, the cap layer CP1 and the first sealing layer SE11 are formed inside the aperture H as well. The organic layer OR1, the upper electrode UE1 and the cap layer CP1 are divided by the overhanging partition 6.

After the process P14, a resist R2 is formed on the first sealing layer SE11 as shown in FIG. 13 (process P15). The resist R2 covers the subpixel SP1 and a part of the partition 6 surrounding it.

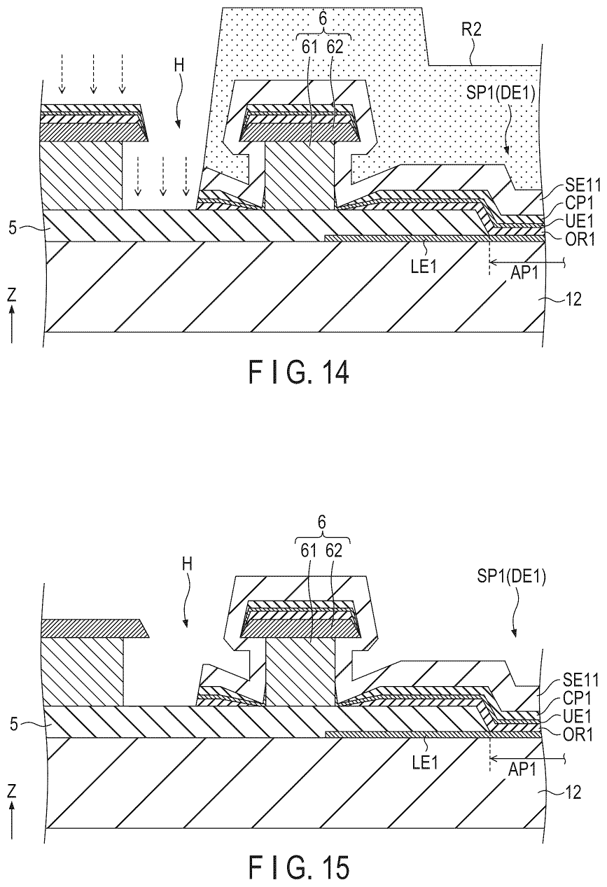

Then, as shown in FIG. 14, the organic layer OR1, the upper electrode UE1, the cap layer CP1 and the first sealing layer SE11 are patterned using the resist R2 as a mask (process P16). This process includes dry etching and wet etching to sequentially remove the portions of the organic layer OR1, upper electrode UE1, cap layer CP1 and first sealing layer SE11, which are exposed from the resist R2.

After process P16, the resist R2 is removed by a stripping solution and residues such as the resist R2 and the like are removed by asking (process P17). Thus, a substrate in which the display element DE1 and the first sealing layer SE11 are formed in the subpixel SP1 can be obtained as shown in FIG. 15.

After forming the display element DE1, the display element DE2 is formed (process P6). The procedures for forming the display element DE2 is similar to those of the processes P11 to P17. That is, as in the cases of the processes P11 to P14, the organic layer OR2, the upper electrode UE2 and the cap layer CP2 are formed in sequence by vapor deposition, and the first sealing layer SE12 is formed by CVD.

After that, as in the case of the process P15, a resist is placed on the first sealing layer SE12, and as in the case of the process P16, the organic layer OR2, the upper electrode UE2, the cap layer CP2 and the first sealing layer SE12 are patterned. After this patterning, the resist is removed as in the case of the process P17.

Through the above-described processes, a substrate in which the display element DE1 and the first sealing layer SE11 are formed in the subpixel SP1 and the display element DE2 and the first sealing layer SE12 are formed in the subpixel SP2, can be obtained.

After forming the display element DE2, the display element DE3 is formed (process P7). The procedures for forming the display element DE3 are similar to those of the processes P11 to P17. That is, as in the cases of the processes P11 to P14, the organic layer OR3, the upper electrode UE3 and the cap layer CP3 are formed in sequence by vapor deposition, and the first sealing layer SE13 is formed by CVD.

After that, as in the case of the process P15, a resist is placed on the first sealing layer SE13, and as in the case of the process P16, the organic layer OR3, the upper electrode UE3, the cap layer CP3 and the first sealing layer SE13 are patterned. After this patterning, the resist is removed as in the case of the process P17.

Through the above-described processes, a substrate in which the display element DE1 and the first sealing layer SE11 are formed in the subpixel SP1, the display element DE2 and the first sealing layer SE12 are formed in the subpixel SP2 and the display element DE3 and the first sealing layer SE13 are formed in the subpixel SP3, can be obtained.

After the process P7, the second sealing layer SE2, the resin layer 13 and the third sealing layer SE3 shown in FIG. 3 are formed in sequence (process P8). Thus, the display device DSP is completed. Note that the above-described manufacturing processes are based on an assumption that the display element DE1 is formed first, then the display element DE2, and finally the display element DE3, but the formation order of the display elements DE1, DE2 and DE3 is not limited to that of this example.

In this embodiment, the partition 6 of the overhanging state is provided at the boundaries of subpixels SP1, SP2 and SP3. In this case, the organic layers OR1, OR2 and OR3, the upper electrodes UE1, UE2 and UE3 and the cap layers CP1, CP2 and CP3, which are formed by vapor deposition, are divided by the partition 6. By covering the respective layers thus divided, by the first sealing layers SE11, SE12 and SE13, the individually sealed display elements DE1, DE2 and DE3 can be obtained. When the display elements DE1, DE2 and DE3 are individually sealed, even if a defect such as the entering of moisture occurs in any one of the display elements, the adverse effect which may spread to other display elements can be suppressed.

Further, in this embodiment, the first sealing layers SE11, SE12 and SE13 are continuously covered by the second sealing layer SE2. With this configuration, the display elements DE1, DE2 and DE3 can be more reliably sealed.

The lower portion 61 of the partition 6 serves to feed electricity to the upper electrodes UE1, UE2 and UE3 and is formed of a light-shielding metal material such as aluminum. Further, the lower electrodes LE1, LE2 and LE3, which reflect light, are arranged in the region surrounded by the partition 6. In such a configuration, the light transparency in the display area DA is significantly reduced.

By contrast, in this embodiment, the apertures H are made in the partition 6. With this configuration, the transparency of the display panel PNL can be enhanced. When the light transparency of the display panel PNL is increased, external light can be detected through the display panel PNL even if the light receiving element RC is arranged over the display panel PNL, as described above with reference to FIG. 4, for example.

In the example of FIG. 2, the aperture H is provided at each of the intersections of the first partitions 6x and the second partitions 6y. At such intersections, the partition 6 is thicker, and therefore it is possible to make a larger aperture H as compared to at other parts of the partition 6.

In addition to the above, various other advantageous effects can be obtained from this embodiment.

### Second Embodiment

The second embodiment will now be described. As to the configurations not specifically referred to, similar ones to those in the first embodiment can be applied.

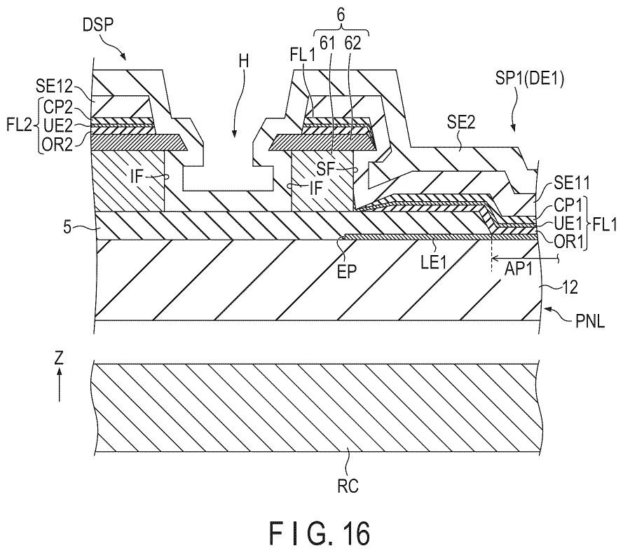

FIG. 16 shows a schematic cross-sectional view of a display device DSP of the second embodiment. In this figure, the substrate 10, the circuit layer 11, the resin layer 13 and the third sealing layer SE3 are omitted from illustration as in the case of FIG. 4.

In this embodiment, the thin films FL1 and FL2 and the first sealing layers SE11 and SE12 are not disposed on an inner side of the aperture H. The inner surface IF of the aperture H is covered by the second sealing layer SE2. The recess created in the second sealing layer SE2 inside the aperture H is filled by the resin layer 13.

In FIG. 16, the configuration of the partition 6 surrounding the subpixel SP1 and its vicinity is mainly shown, but the configuration of the partition 6 surrounding the subpixels SP2 and SP3 and its vicinity is also similar to that of the example in FIG. 16. In other words, in this embodiment, the thin films FL1, FL2 and FL3 are not disposed on the inner side of each aperture H.

Note here that all the apertures H in the partition 6 do not necessarily have to have the configuration shown in FIG. 16. For example, the thin films FL1, FL2 and FL3 may be disposed as in the example of FIG. 4 on the inner side of at least one aperture H.

Although the thin films FL1, FL2 and FL3 are translucent, they absorb or reflect some of the light that passes therethrough. In the apertures H where the thin films FL1, FL2 and FL3 are not disposed as seen in the example of FIG. 16, such absorption or reflection does not occur, and thus the transparency of the display panel PNL can be further enhanced.

Note here that when the thin films FL1, FL2 and FL3 are not disposed in the apertures H, the rib 5 may be exposed to the etching of the first sealing layers SE11, SE12 and SE13 through the apertures H in the patterning process P16 shown in FIG. 14. When the rib 5 is formed of the same material as that of the first sealing layers SE11, SE12 and SE13, the rib 5 may be damaged by this etching.

In order to avoid this, it is preferable that at least the topmost surface of the rib 5 be formed of a material whose etching rate for the first sealing layers SE11, SE12 and SE13 is lower than that of the first sealing layers SE11, SE12 and SE13 for this etching. For example, such a relationship of etching rate can be achieved when the first sealing layers SE11, SE12 and SE13 are formed of silicon nitride and the rib 5 is formed of silicon oxide or silicon oxynitride.

### Third Embodiment

The third embodiment will now be described. As to the configurations not specifically referred to, similar ones to those in the above-provided embodiments can be applied.

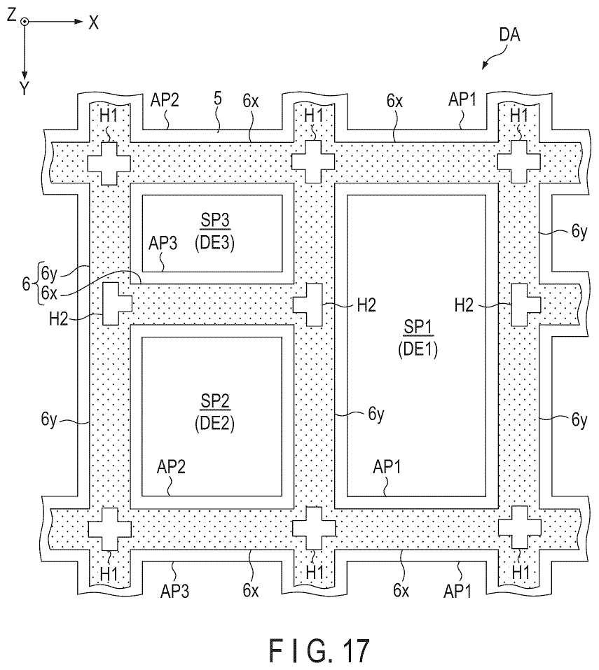

FIG. 17 is a schematic plan view of apertures H according to the third embodiment. In this embodiment, the apertures H have polygonal shapes.

More specifically, a plurality of apertures H arranged in the display area DA include cross-shaped first apertures H1 and T-shaped second apertures H2. The first apertures H1 are each provided at the intersections where the first partitions 6x and the second partitions 6y intersect in a cross-shaped manner, respectively. The second apertures H2 are each provided at the intersections where the first partitions 6x and the second partitions 6y are connected in a T-shape manner, respectively.

As in this embodiment, by providing apertures H of different shapes according to the respective shapes of the intersections of the first partitions 6x and the second partitions 6y, the area of the apertures H can be increased. With this configuration, the transparency of the display panel PNL can be further improved.

### Fourth Embodiment

The fourth embodiment will now be described. As to the configurations not specifically referred to, similar ones to those in the above-provided embodiments can be applied.

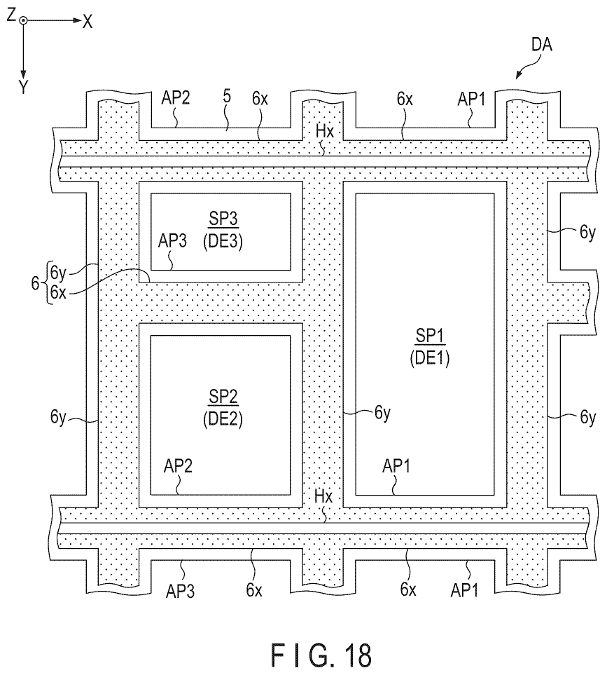

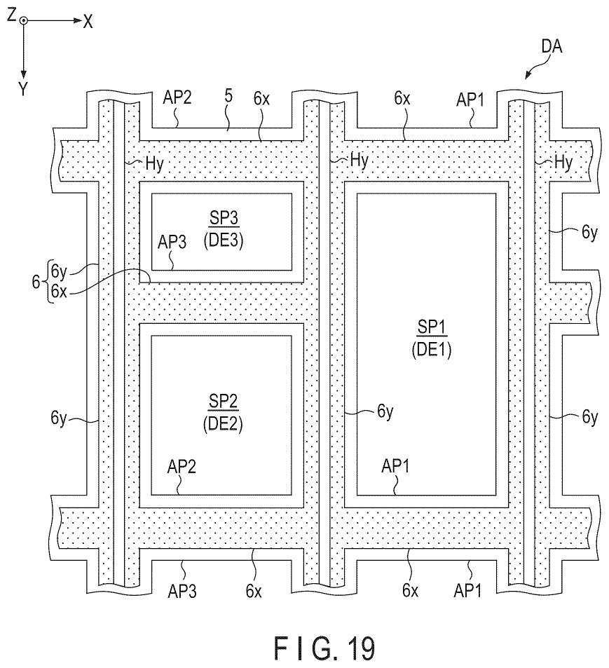

FIG. 18 is a schematic plan view of an example of the apertures H according to the fourth embodiment. FIG. 19 is a schematic plan view showing another example of the apertures H for the fourth embodiment. As shown in these figures, in this embodiment, the apertures H are slits. In the following description, the apertures H shown in FIG. 18 are referred to as apertures Hx and the apertures H shown in FIG. 19 are referred to as apertures Hy.

In the example of FIG. 18, the apertures Hx are provided in the first partitions 6x. The apertures Hx extend long in the first direction X. The direction of extension of the apertures Hx is parallel to the scanning lines GL shown in FIG. 1. For example, the length of the apertures Hx is greater than the width of the pixel apertures AP1, AP2 and AP3 along the first direction X. The apertures Hx may be formed continuously or intermittently from one end to the other end of the display area DA along the first direction X.

In the example of FIG. 19, the apertures Hy are provided in the second partitions 6y. The apertures Hy extend long in the second direction Y. The direction of extension of the apertures Hy is parallel to the signal lines SL shown in FIG. 1. For example, the length of the apertures Hy is greater than the width of the pixel apertures AP1, AP2 and AP3 along the second direction Y. The apertures Hy may be formed continuously or intermittently from one end to the other end of the display area DA along the second direction Y.

For the apertures Hx, Hy, the configuration shown, for example, in FIG. 4 or FIG. 16 can be applied. The partitions 6 with the apertures Hx and Hy can be fabricated by the processes shown in FIGS. 6 to 11, for example. At least a portion of the apertures Hx and Hy overlap the light receiving elements RC shown in FIGS. 1 and 3 in plan view.

Note that the partition 6 may as well include both apertures Hx and Hy. In this case, the apertures Hx and the apertures Hy may be connected respectively at the intersections of the first partitions 6x and the second partitions 6y.

With such slit-shaped apertures H (Hx and Hy) provided as in this embodiment, the area of the apertures H can be further increased than that of each of the above-provided embodiments. With this configuration, the transparency of the display panel PNL can be further improved.

All of the display devices and manufacturing methods therefor that can be implemented by a person of ordinary skill in the art through arbitrary design changes based on the display devices and the manufacturing methods described above as the embodiments and the modified examples of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a process or changing the condition of a process, all of the modifications fall within the scope of the present invention as long as they are in keeping with the spirit of the invention.

Further, other effects which may be obtained from each of the above embodiments and modified examples and are self-explanatory from the descriptions of the specification or can be arbitrarily conceived by a person of ordinary skill in the art are considered to be naturally brought about by the present invention as a matter of course.

What is claimed is:

1. A display device comprising:
a plurality of display elements each including a lower electrode, an upper electrode opposing the lower electrode and an organic layer disposed between the lower electrode and the upper electrode, which emits light according to a potential difference between the lower electrode and the upper electrode; and
a partition which surrounds each of the plurality of display elements and includes a conductive lower portion and an upper portion protruding from a side surface of the lower portion,
wherein the partition comprising an aperture through which the lower portion and the upper portion penetrate.

2. The display device of claim 1, wherein
the partition includes
a first partition extending in a first direction; and
a second partition connected to the first partition and extending in a second direction which intersects the first direction, and
the aperture is provided at an intersection of the first partition and the second partition.

3. The display device of claim 1, wherein
a portion of the upper electrode and the organic layer is disposed on an inner side of the aperture.

4. The display device of claim 1, wherein
the upper electrode and the organic layer are not disposed on an inner side of the aperture.

5. The display device of claim 1, further comprising:
a plurality of first sealing layers which individually cover the plurality of display elements, respectively; and
a second sealing layer which continuously covers the plurality of first sealing layers.

6. The display device of claim 5, wherein
an inner surface of the aperture is covered by the first sealing layer or the second sealing layer.

7. The display device of claim 1, further comprising:
an insulating rib which surrounds each of the plurality of display elements,
wherein
an end portion of the lower electrode is covered by the rib,
the partition is disposed on the rib, and
the aperture is provided at a position that does not overlap the lower electrode in plan view.

8. The display device of claim 1, wherein
the aperture is circular.

9. The display device of claim 1, wherein
the aperture is polygonal.

10. The display device of claim 1, wherein
the aperture is a slit extending in a straight line.

11. The display device of claim 1, further comprising:
a light receiving element which overlaps the aperture in plan view and is configured to detect light passing through the aperture.

12. The display device of claim 11, further comprising:
a controller configured to adjust luminance of the plurality of display elements based on a signal output by the light receiving element.

13. A display device comprising:
a plurality of display elements each including a lower electrode, an upper electrode opposing the lower electrode and an organic layer disposed between the lower electrode and the upper electrode, which emits light according to a potential difference between the lower electrode and the upper electrode; and
a partition which surrounds each of the plurality of display elements and includes a conductive lower portion and an upper portion protruding from a side surface of the lower portion,
wherein the partition comprising a slit.

14. The display device of claim 13, further comprising:
a pixel circuit which supplies a pixel voltage to the lower electrode; and
a scanning line which supplies a scanning signal to the pixel circuit,
wherein
a direction of extension of the slit is parallel to the scanning line.

15. The display device of claim 13, further comprising:
a pixel circuit which supplies a pixel voltage to the lower electrode; and
a signal line which supplies a video signal to the pixel circuit,
wherein
a direction of extension of the slit is parallel to the signal line.

16. The display device of claim 13, wherein
a portion of the upper electrode and the organic layer is disposed on an inner side of the slit.

17. The display device of claim 13, further comprising:
a plurality of first sealing layers which individually cover the plurality of display elements, respectively; and
a second sealing layer which continuously covers the plurality of first sealing layers.

18. The display device of claim 17, wherein
an inner surface of the slit is covered by the first sealing layers or the second sealing layer.

19. The display device of claim 13, further comprising:
an insulating rib which surrounds each of the plurality of display elements,
wherein
an end portion of the lower electrode is covered by the rib,
the partition is disposed on the rib, and
the slit is provided at a position which does not overlap the lower electrode in plan view.

20. The display device of claim 13, further comprising:
a light receiving element which overlaps the slit in plan view and is configured to detect light passing through the slit.
